(19) United States
(12) Patent Application Publication
(10) Pub. No.: US 2025/0312830 A1
(43) Pub. Date: Oct. 9, 2025

(54) SUBSTRATE CLEANING DEVICE, SUBSTRATE PROCESSING DEVICE, SUBSTRATE CLEANING METHOD, AND SUBSTRATE PROCESSING METHOD

(71) Applicant: EBARA CORPORATION, Tokyo (JP)

(72) Inventors: Takayuki KAJIKAWA, Tokyo (JP); Naoyuki HANDA, Tokyo (JP); Tomoya NISHI, Tokyo (JP)

(21) Appl. No.: 18/865,038

(22) PCT Filed: May 11, 2023
(86) PCT No.: PCT/JP2023/017651

§ 371 Date: Dec. 16, 2024

(30) Foreign Application Priority Data
May 13, 2022 (JP) 2022-079154

(51) Int. Cl. B08B 3/02; B08B 1/34; B24B 37/34

(52) U.S. Cl. CPC B08B 3/02; B08B 1/34; B24B 37/34; B08B 2203/02

(57) ABSTRACT

To enable cleaning of a lower surface of a substrate.

Provided is a substrate cleaning device including a first scrub cleaning member that scrubs and cleans a lower surface of a substrate that is a cleaning target, a first single-tube nozzle that supplies a cleaning liquid to a vicinity of a center of the lower surface of the substrate, and a first spray nozzle that supplies the cleaning liquid to the lower surface of the substrate.

### TECHNICAL FIELD

The present invention relates to a substrate cleaning device, a substrate processing apparatus, a substrate cleaning method, and a substrate processing method.

### BACKGROUND ART

Patent Literatures 1 to 5 disclose a substrate cleaning device that cleans an upper surface of a substrate.

### CITATION LIST

### Patent Literature

Patent Literature 1: Japanese Patent No. 6600470

Patent Literature 2: Japanese Patent No. 6710129

Patent Literature 3: Japanese Patent No. 6877221

Patent Literature 4: Japanese Patent No. 6964745

Patent Literature 5: WO 2021/230344 A

### SUMMARY OF INVENTION

### Technical Problem

An object of the present invention is to clean a lower surface of a substrate.

### Solution to Problem

According to one embodiment of the invention, provided is
[1] a substrate cleaning device comprising:
   a first scrub cleaning member that scrubs and cleans a lower surface of a substrate that is a cleaning target;
   a first single-tube nozzle that supplies cleaning liquid to a vicinity of a center of the lower surface of the substrate; and
   a first spray nozzle that supplies cleaning liquid to the lower surface of the substrate.
[2] In the substrate cleaning device according to [1], it is preferable that a liquid landing region of the cleaning liquid supplied from the first spray nozzle covers a region from a vicinity of a center of the substrate to a vicinity of an edge of the substrate.
[3] It is preferrable that the substrate cleaning device according to [1] or [2], further comprises at least one of:
   a second single-tube nozzle that is disposed at a position point-symmetrical to the first single-tube nozzle with respect to the center of the substrate when viewed from vertically above and supplies cleaning liquid to a region that is in a vicinity of the center of the lower surface of the substrate and is different from cleaning liquid supply region from the first single-tube nozzle; and
   a second spray nozzle that is disposed at a position point-symmetrical to the first spray nozzle with respect to the center of the substrate when viewed from vertically above and supplies cleaning liquid to the lower surface of the substrate.

According to one embodiment of the invention, provided is
[4] a substrate cleaning device comprising:
   a first scrub cleaning member that scrubs and cleans a lower surface of a substrate that is a cleaning target;
   a first single-tube nozzle that supplies cleaning liquid to a vicinity of a center of the lower surface of the substrate; and
   a second single-tube nozzle that supplies cleaning liquid to a region different from the vicinity of the center of the lower surface of the substrate.
[5] It is preferrable that the substrate cleaning device according to [4], further comprises at least one of:
   a third single-tube nozzle that is disposed at a position point-symmetrical to the first single-tube nozzle with respect to the center of the substrate when viewed from vertically above and supplies cleaning liquid to a region that is in a vicinity of the center of the lower surface of the substrate and is different from cleaning liquid supply region from the first single-tube nozzle; and
   a fourth single-tube that is disposed at a position point-symmetrical to the second single-tube nozzle with respect to the center of the substrate when viewed from vertically above and supplies cleaning liquid to a region that is different from the vicinity of the center of the lower surface of the substrate.
[6] It is preferrable that the substrate cleaning device according to [1] to [5], further comprises:
   a second scrub cleaning member that scrubs and cleans an upper surface of the substrate;
   a fifth single-tube nozzle that supplies cleaning liquid to a vicinity of a center of the upper surface of the substrate; and
   a sixth single-tube nozzle that supplies cleaning liquid to a region different from the vicinity of the center of the upper surface of the substrate.

According to one embodiment of the invention, provided is
[7] a substrate cleaning device comprising:
   a first nozzle that is a single-tube nozzle that supplies pure water to a vicinity of a center of a lower surface of a substrate that is a cleaning target; and
   a second nozzle that is a spray nozzle that supplies pure water to the lower surface of the substrate.
[8] It is preferrable that the substrate cleaning device according to [7], further comprises at least one of:
   a third nozzle that is a single-tube nozzle that is disposed at a position point-symmetrical to the first nozzle with respect to the center of the substrate when viewed from vertically above and supplies pure water to a region that is in a vicinity of the center of the lower surface of the substrate and is different from pure water supply region from the first nozzle; and
   a fourth nozzle that is a spray nozzle that is disposed at a position point-symmetrical to the second nozzle with respect to the center of the substrate when viewed from vertically above and supplies pure water to the lower surface of the substrate.

According to one embodiment of the invention, provided is
[9] A substrate cleaning device comprising:
   a first nozzle that is a single-tube nozzle that supplies pure water to a vicinity of a center of a lower surface of a substrate that is a cleaning target; and
   a second nozzle that is a single-tube nozzle that supplies pure water to a region different from a vicinity of the center of the lower surface of the substrate.
[10] It is preferrable that the substrate cleaning device according to [9], further comprises at least one of:
   a third nozzle that is a single-tube nozzle disposed at a position point-symmetrical to the first nozzle with respect to the center of the substrate when viewed from vertically above and supplies pure water to a region that is in the vicinity of the center of the lower surface of the substrate and is different from pure water supply region from the first nozzle; and
   a fourth nozzle that is a single-tube nozzle disposed at a position point-symmetrical to the second nozzle with respect to the center of the substrate when viewed from vertically above and supplies pure water to a region different from the vicinity of the center of the lower surface of the substrate.
[11] It is preferrable that the substrate cleaning device according to one of [7] to [10], further comprises
   a substrate rotation mechanism configured to rotate the substrate, and that
   a supply direction of the pure water supplied from the first nozzle and a tangential direction of a rotation direction of the substrate in a liquid landing region of the pure water supplied from the second nozzle are opposite directions.
[12] It is preferrable that the substrate cleaning device according to one of [7] to [10], further comprises
   a substrate rotation mechanism configured to rotate the substrate, and that
   a supply direction of the pure water supplied from the first nozzle and a tangential direction of a rotation direction of the substrate in a liquid landing region of the pure water supplied from the second nozzle are identical directions.
[13] In the substrate cleaning device according to [12], it is preferrable that an angle formed by the substrate and the supply direction of the pure water supplied from the first nozzle is 10 to 60 degrees.

According to one embodiment of the invention, provided is
[14] a substrate processing apparatus comprising:
   a substrate polishing device that polishes a substrate by using a polishing liquid;
   a first substrate cleaning device that is the substrate cleaning device according to one of [1] to [6], and scrubs and cleans the substrate polished by the substrate polishing device by using cleaning liquid; and
   a second substrate cleaning device that is the substrate cleaning device according to one of [7] to [13], and cleans the substrate cleaned by the first substrate cleaning device by using pure water.

According to one embodiment of the invention, provided is
[15] a substrate cleaning method comprising a cleaning step of supplying a cleaning liquid from a single-tube nozzle to a vicinity of a center of a lower surface of a substrate that is a cleaning target while scrubbing and cleaning the lower surface of the substrate, and supplying the cleaning liquid from a spray nozzle to the lower surface of the substrate.

According to one embodiment of the invention, provided is
[16] a substrate cleaning method comprising a cleaning step of supplying a cleaning liquid from a first single-tube nozzle to a vicinity of a center of a lower surface of a substrate that is a cleaning target while scrubbing and cleaning the lower surface of the substrate, and supplying the cleaning liquid from a second single-tube nozzle to a region different from the vicinity of the center of the lower surface of the substrate.
[17] In the substrate cleaning method according to [15] or [16], it is preferable that the cleaning step is performed after the substrate is polished by using a polishing liquid to remove the polishing liquid from the lower surface of the substrate.

According to one embodiment of the invention, provided is
[18] a substrate cleaning method comprising a cleaning step of supplying pure water from a single-tube nozzle to a vicinity of a center of a lower surface of a substrate that is a cleaning target, and supplying the pure water from a spray nozzle to the lower surface of the substrate.

According to one embodiment of the invention, provided is [19]
a substrate cleaning method comprising a cleaning step of supplying pure water from a first single-tube nozzle to a vicinity of a center of a lower surface of a substrate that is a cleaning target, and supplying the pure water from a second single-tube nozzle to a region different from the vicinity of the center of the lower surface of the substrate.
[20] In the substrate cleaning method according to [18] or [19], it is preferrable that the cleaning step is performed after cleaning a substrate by using a cleaning liquid to remove the cleaning liquid from the lower surface of the substrate.

According to one embodiment of the invention, provided is
[21] a substrate processing method comprising:
   a substrate polishing step of polishing a substrate by using a polishing liquid;
   a first substrate cleaning step of cleaning the polished substrate in the substrate cleaning method according to claim 15 or 16 by using a cleaning liquid after the substrate polishing step to remove the polishing liquid from a lower surface of the substrate; and
   a second substrate cleaning step of cleaning the cleaned substrate in the substrate cleaning method according to claim 18 or 19 after the first substrate cleaning step to remove the cleaning liquid from the lower surface of the substrate.

### Advantageous Effects of Invention

A lower surface of a substrate can be cleaned.

### BRIEF DESCRIPTION OF DRAWINGS

FIG. 1 is a block diagram illustrating a schematic configuration of a substrate processing apparatus 100.

FIG. 2 is a schematic perspective view of a substrate cleaning device 2 according to a first embodiment.

FIG. 3 is a diagram for describing a cleaning liquid supply region from cleaning liquid supply nozzles 51 and 52.

FIG. 4A is a view schematically illustrating a state of cleaning in a case where a rotation direction of a substrate W in a liquid landing region coincides with a supply direction of a cleaning liquid.

FIG. 4B is a view schematically illustrating a state of cleaning in a case where the rotation direction of the substrate W in the liquid landing region does not coincide with the supply direction of the cleaning liquid.

FIG. 5 is a view illustrating an experimental result of comparing the cleanability on a lower surface of the substrate W between the substrate cleaning device 2 according to the first embodiment and a substrate cleaning device according to a comparative example.

FIG. 6A is a schematic perspective view of a substrate cleaning device 2 which is a modification of the substrate cleaning device 2 in FIG. 2.

FIG. 6B is a diagram for describing cleaning liquid supply regions from cleaning liquid supply nozzles 51, 52, 51′, and 52′.

FIG. 7 is a diagram for describing cleaning liquid supply regions from single-tube nozzles 51 and 53.

FIG. 8 is a diagram illustrating an experimental result of comparing the cleanability on the lower surface of the substrate W between a substrate cleaning device 2′ according to a second embodiment and a substrate cleaning device according to a comparative example.

FIG. 9 is a diagram for describing cleaning liquid supply regions from single-tube nozzles 51, 53, 51′, and 53′.

FIG. 10 is a schematic perspective view of a substrate cleaning device 3 according to a third embodiment.

FIG. 11A is a view schematically illustrating a state of cleaning in a case where a rotation direction of a substrate W in a liquid landing region does not coincide with a supply direction of a cleaning liquid.

FIG. 11B is a view schematically illustrating a state of cleaning in a case where the rotation direction of the substrate W in the liquid landing region coincides with the supply direction of the cleaning liquid.

FIG. 12 is a diagram for describing a desirable pure water supply region from a single-tube nozzle 81.

FIG. 13 is a view experimentally illustrating a relationship between a liquid landing region of pure water and detergency.

FIG. 14 is a diagram experimentally illustrating a relationship between a vertical angle and detergency.

FIG. 15 is a diagram for describing a desirable pure water supply region from a spray nozzle 82.

FIG. 16 is a diagram for describing desirable disposition of the pure water supply nozzles 81 and 82 when viewed from vertically above.

FIG. 17 is a view illustrating an experimental result of comparing the cleanability on the lower surface of the substrate W between the substrate cleaning device 3 according to the third embodiment and a substrate cleaning device according to a comparative example.

FIG. 18 is a schematic perspective view of a substrate cleaning device 3 which is a modification of the substrate cleaning device 3 in FIG. 10.

FIG. 19 is a diagram illustrating an experimental result of comparing the cleanability on the lower surface of the substrate W between a substrate cleaning device 3 according to a fourth embodiment and a substrate cleaning device according to a comparative example.

### DESCRIPTION OF EMBODIMENTS

Hereinafter, embodiments of the present invention will be described in detail with reference to the drawings.

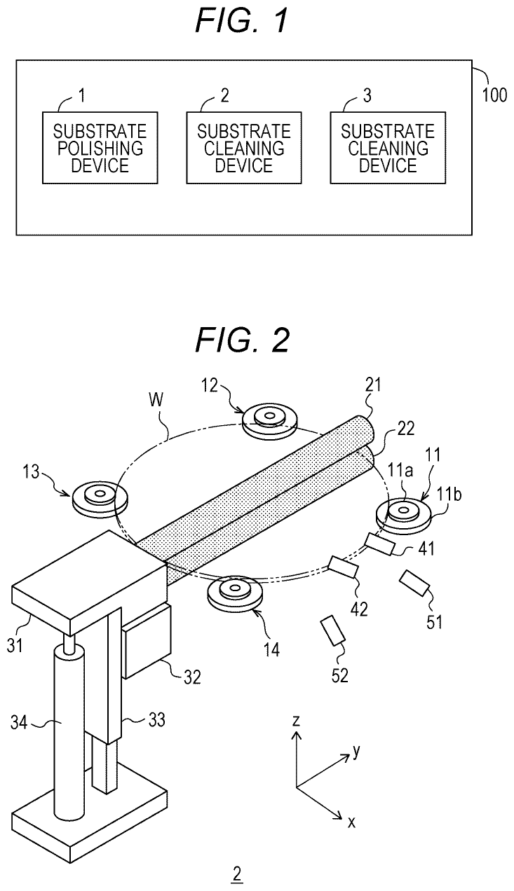

FIG. 1 is a block diagram illustrating a schematic configuration of a substrate processing apparatus 100. The substrate processing apparatus 100 includes a substrate polishing device 1 and substrate cleaning devices 2 and 3. Note that the type, a shape, and a size of a substrate that is a processing target are not particularly limited, and may be, for example, a circular semiconductor wafer having a diameter of 300 mm.

The substrate polishing device 1 polishes a front surface and/or a bevel of a substrate by using a polishing liquid. A defect such as a polishing liquid or a polishing waste adheres to an upper surface (front surface) and a lower surface (back surface) of the substrate after polishing. Since a known substrate polishing device may be employed as the substrate polishing device 1, a description thereof will be omitted.

The substrate cleaning device 2 cleans the upper surface and the lower surface of the substrate after being polished by the substrate polishing device 1 by using a cleaning liquid while performing scrubbing and cleaning, thereby removing the defect. The cleaning liquid may be a chemical liquid or pure water (deionized water: DIW). The cleaning liquid remains on the upper surface and the lower surface of the substrate after cleaning. A configuration of the substrate cleaning device 2 will be described in the first and second embodiments.

The substrate cleaning device 3 cleans the upper surface and the lower surface of the substrate cleaned by the substrate cleaning device 2 by using pure water, and replaces the remaining cleaning liquid with the pure water. A configuration of the substrate cleaning device 3 will be described in the third and fourth embodiments.

Although not illustrated, the substrate processing apparatus 100 includes a transport device that transports a substrate that is a processing target from a load port (not illustrated) to the substrate polishing device 1, a transport device that transports the substrate polished by the substrate polishing device 1 to the substrate cleaning device 2, and a transport device that transports the substrate cleaned by the substrate cleaning device 2 to the substrate cleaning device 3. Further, the substrate processing apparatus 100 may include a substrate drying device that dries the cleaned substrate.

### First Embodiment

In the first embodiment, the substrate cleaning device 2 will be described in detail.

FIG. 2 is a schematic perspective view of the substrate cleaning device 2 according to the first embodiment. The substrate cleaning device 2 includes substrate rotation mechanisms 11 to 14, scrub cleaning members 21 and 22, rotation mechanisms 31 and 32, a guide rail 33, a lifting/lowering drive mechanism 34, cleaning liquid supply nozzles 41 and 42 for an upper surface, and cleaning liquid supply nozzles 51 and 52 for a lower surface.

The substrate rotation mechanisms 11 to 14 hold and rotate a substrate W. In the present embodiment, the substrate rotation mechanisms 11 to 14 hold the substrate W in a horizontal direction and rotate the substrate W in a horizontal plane. Here, a rotation speed is, for example, 50 to 500 rpm.

Specifically, the substrate rotation mechanism 11 is a roller including a holder 11a and a shoulder module (supporter) 11b. A diameter of the shoulder module 11b is larger than a diameter of the holder 11a, and the holder 11a is provided on the shoulder module 11b. The substrate rotation mechanisms 12 to 14 also have the same configuration as that of the substrate rotation mechanism 11. The substrate rotation mechanisms 11 to 14 are movable in directions of approaching and separating from each other by a drive mechanism (for example, an air cylinder) (not illustrated). When the substrate rotation mechanisms 11 to 14 are close to each other, the holders 11a to 14a can hold the substrate W substantially horizontally. In addition, at least one of the substrate rotation mechanisms 11 to 14 is configured to be rotationally driven by a rotation mechanism (not illustrated), so that the substrate W can be rotated in a horizontal plane.

Note that a substrate surface facing upward in the vertical direction when held by the substrate rotation mechanisms 11 to 14 will be referred to as an upper surface of the substrate W, and a substrate surface facing downward in the vertical direction will be referred to as a lower surface of the substrate W. Usually, a device is formed on the upper surface of the substrate W.

The scrub cleaning member 21 contacts the upper surface of the substrate W to scrub and clean the upper surface of the substrate W. In the present embodiment, the scrub cleaning member 21 is a roll type formed of sponge or the like, and is disposed to extend in the horizontal direction from the edge of the substrate W to the opposite edge through the center.

The scrub cleaning member 21 is rotated about the longitudinal direction of the scrub cleaning member 21 by the rotation mechanism 31. The rotation mechanism 31 is attached to the guide rail 33 that guides the movement in the up-down direction, and is supported by the lifting/lowering drive mechanism 34. The rotation mechanism 31 and the scrub cleaning member 21 are moved in the up-down direction along the guide rail 33 by the lifting/lowering drive mechanism 34.

The scrub cleaning member 22 is disposed below the scrub cleaning member 21 and contacts the lower surface of the substrate W to scrub and clean the lower surface of the substrate W. In the present embodiment, the scrub cleaning member 22 is a roll type formed of sponge or the like, and is disposed to extend in the horizontal direction from the edge of the substrate W to the opposite edge through the center.

The scrub cleaning member 22 is rotated about the longitudinal direction of the scrub cleaning member 22 by the rotation mechanism 32. Although the lifting/lowering drive mechanism and the like are not illustrated, the rotation mechanism 32 and the scrub cleaning member 22 are also moved in the up-down direction similarly to the scrub cleaning member 21.

The cleaning liquid supply nozzles 41 and 42 are disposed above the substrate W and supply a cleaning liquid to the upper surface of the substrate W. As an example, the cleaning liquid supply nozzle 41 is a single-tube nozzle, and supplies the cleaning liquid to the vicinity of the center of the upper surface of the substrate W. The cleaning liquid supply nozzle 42 is also a single-tube nozzle, and supplies the cleaning liquid to a position (for example, between the center and the edge) different from the vicinity of the center of the upper surface of the substrate W. As a specific example, tip diameters of the cleaning liquid supply nozzles 41 and 42 may be 1.0 mm in diameter. However, the type and number of the cleaning liquid supply nozzles 41 and 42 are not limited, and may be omitted in some cases.

The cleaning liquid supply nozzles 51 and 52 are disposed below the substrate W and supply a cleaning liquid to the lower surface of the substrate W. As one feature of the present embodiment, the cleaning liquid supply nozzle 51 is a single-tube nozzle (hereinafter, referred to as a “single-tube nozzle 51” in some cases). A radius of the single-tube nozzle 51 is, for example, 0.5 to 3 mm. On the other hand, the cleaning liquid supply nozzle 52 is a spray nozzle (hereinafter, referred to as a “spray nozzle 52” in some cases). A spread angle thereof is, for example, 50 to 150 degrees.

When both nozzles are compared, large droplets are continuously supplied from the single-tube nozzle 51 to a narrow region on the lower surface of the substrate W, so that the striking force is strong. On the other hand, from the spray nozzle 52, small droplets are supplied to a wide region on the lower surface of the substrate W while being discontinuously dispersed, so that the striking force is weak.

The cleaning liquid used in the substrate cleaning device 2 may be a chemical liquid or pure water. The chemical liquid may be, for example, an organic solvent or a heated one, and the pure water may be ultrasonic water or may contain microbubbles. The cleaning liquid from one nozzle may be a chemical liquid, and the cleaning liquid from the other nozzle may be pure water. Alternatively, the cleaning liquid from both the nozzles may be a chemical liquid, or the cleaning liquid from both the nozzles may be pure water.

In addition, it is desirable to simultaneously start and stop the supply of the cleaning liquid from the cleaning liquid supply nozzles 51 and 52. A flow rate balance of the cleaning liquids supplied from the cleaning liquid supply nozzles 51 and 52 is freely selected, and for example, both are 500 ml/min. A total flow rate of the cleaning liquids supplied from the cleaning liquid supply nozzles 51 and 52 is, for example, 500 to 4000 ml/min.

The cleaning liquid supply nozzles 51 and 52 may be displaced in the horizontal direction or may be displaced in the vertical direction.

For convenience of the following description, the center of the held substrate W is defined as an origin, the direction in which the scrub cleaning members 21 and 22 extend is defined as a y direction (a side on which the rotation mechanism 31 is provided is defined as negative), the direction orthogonal to the y direction in the horizontal plane is defined as an x direction (a side on which the cleaning liquid supply nozzles 51 and 52 are provided is defined as positive), and the vertical direction is defined as a z direction (an up direction is defined as positive). For example, in FIG. 2, the cleaning liquid supply nozzles 51 and 52 are disposed in a region of x>0 and z<0.

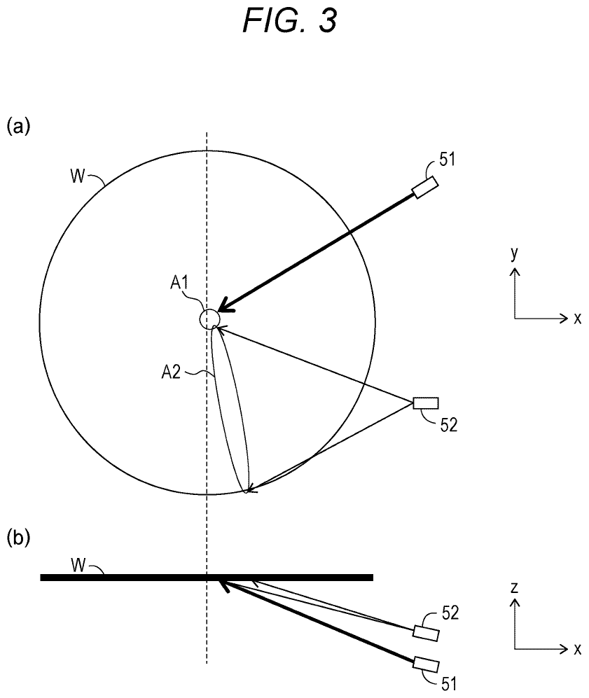

FIG. 3 is a diagram for describing a cleaning liquid supply region from the cleaning liquid supply nozzles 51 and 52, in which FIG. 3(a) corresponds to a view of the substrate W viewed from below in the +z direction, and FIG. 3(b) corresponds to a view of the substrate W viewed from the side in the +y direction (however, the scrub cleaning member 22 is not illustrated).

As illustrated in the drawing, the cleaning liquid from the single-tube nozzle 51 is supplied to a narrow liquid landing region A1 including the vicinity of the center of the substrate W (the “vicinity of the center” desirably includes the center, but need not include the center). It can also be said that the liquid landing region A1 of the cleaning liquid from the single-tube nozzle 51 is in the vicinity of the origin.

On the other hand, the cleaning liquid from the spray nozzle 52 is supplied to a wide liquid landing region A2 covering the edge from the vicinity of the center of the substrate W while spreading in a fan shape or a conical shape. The liquid landing region A2 of the cleaning liquid from the spray nozzle 52 is a region of x≈0 and y<0. The direction from the spray nozzle 52 toward the center of the liquid landing region A2 in the longitudinal direction will be referred to as a cleaning liquid supply direction of the spray nozzle 52. The cleaning liquid supply direction is substantially the −x direction.

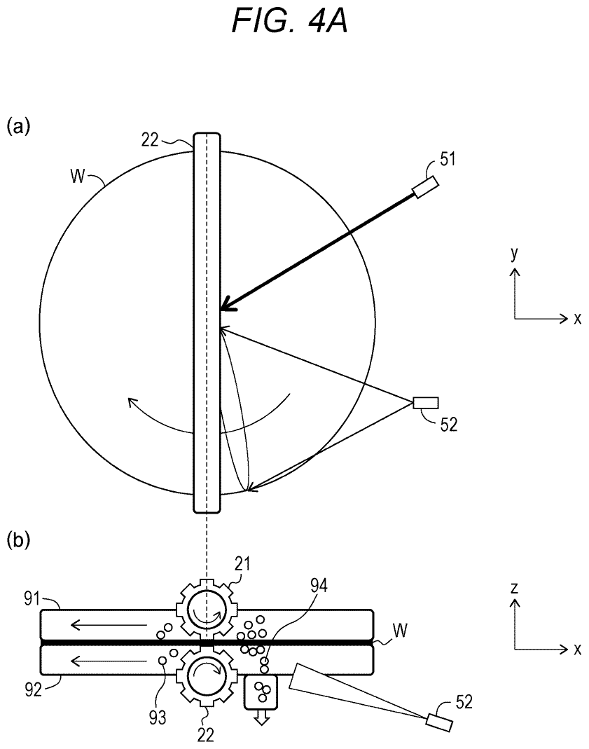

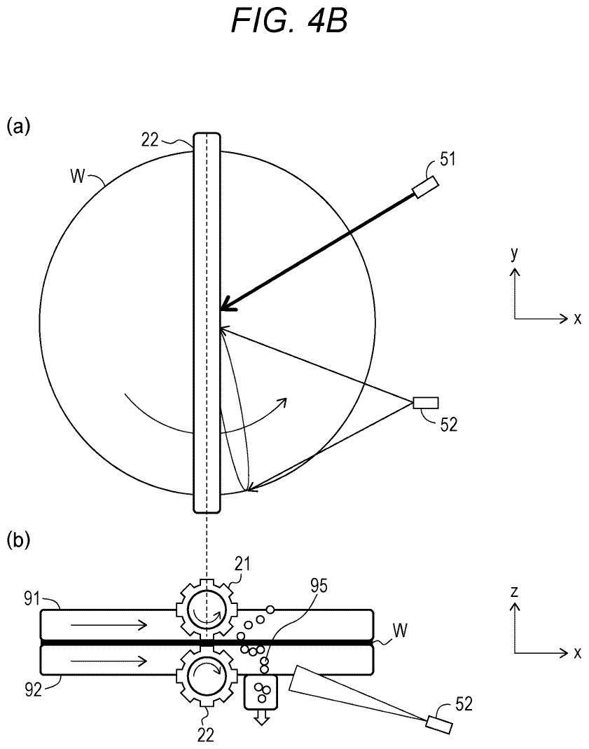

FIG. 4A is a view schematically illustrating a state of cleaning in a case where a rotation direction of the substrate W in the liquid landing region coincides with the supply direction of the cleaning liquid, FIG. 4A(a) corresponds to a view of the substrate W viewed from below in the +z direction, and FIG. 4A(b) corresponds to a view of the substrate W viewed from the side in the +y direction.

As illustrated in FIG. 4A(a), the substrate W is rotated clockwise when viewed from below. A tangential direction of the rotation direction of the substrate W in the liquid landing region (a region of x≈0 and y<0) of the cleaning liquid from the spray nozzle 52 is the −x direction. The cleaning liquid supply direction from the cleaning liquid supply nozzles 51 and 52 is also the −x direction. As described above, the tangential direction of the rotation direction of the substrate W in the liquid landing region coincides with the supply direction of the cleaning liquid (both are the −x direction).

FIG. 4A(b) illustrates an example in which the rotation direction of the scrub cleaning member 21 is a counterclockwise direction when viewed from the side in the +y direction, and the rotation direction of the scrub cleaning member 22 is a clockwise direction (that is, in the region where the cleaning liquid is supplied from the spray nozzle 52, at the position where the scrub cleaning members 21 and 22 contact the substrate W, the tangential direction of the rotation direction of the scrub cleaning members 21 and 22 and the tangential direction of the rotation direction of the substrate W are opposite to each other). However, the rotation directions may be reverse.

As illustrated in the drawing, cleaning liquid layers 91 and 92 are respectively formed on the upper surface and the lower surface of the substrate W, and flow in the same direction (that is, the −x direction) as the tangential direction of the rotation direction of the substrate W. The flow of the cleaning liquid becomes slower as the cleaning liquid becomes closer to the substrate W in the cleaning liquid layers 91 and 92. For example, in a case where the substrate W is rotated at 100 rpm and the cleaning liquid is supplied at 1 L/min, the cleaning liquid present in a portion at a distance of about 10 μm or less from the substrate W flows particularly slowly, that is, about 20 mm/s (estimated value), and is called a low viscosity layer.

In addition, a defect such as a polishing liquid or a polishing waste adheres to the upper surface and the lower surface of the substrate W. This defect is scraped out from the upper surface and the lower surface of the substrate W by the scrub cleaning members 21 and 22.

On the lower surface of the substrate W, some scraped defects 93 are caused to flow in the −x direction along with the flow of the cleaning liquid layer 92, and the cleaning liquid from the single-tube nozzle 51 has a large striking force, and is thus guided to the edge of the substrate W and efficiently discharged in the horizontal direction.

Further, some of the scraped defects 94 are caused to flow in the +x direction due to the rotation of the scrub cleaning member 22. In this case, droplets of the cleaning liquid from the spray nozzle 52 discontinuously collide, and since the momentum (mass) of the droplets is small, the droplets are easily repelled by the flow of the cleaning liquid layer 92 and do not enter the low adhesive layer. As a result, the flow of the cleaning liquid layer 92 increases, and the attached substance can be efficiently removed.

As described above, when the supply direction of the cleaning liquid in the liquid landing region coincides with the tangential direction of the rotation direction of the substrate W, the cleaning liquid supply from the single-tube nozzle 51 and the spray nozzle 52 effectively acts on the lower surface of the substrate W, and the defects 94 can be efficiently removed.

FIG. 4B is a diagram schematically illustrating a state of cleaning in a case where the rotation direction of the substrate W in the liquid landing region does not coincide with the supply direction of the cleaning liquid. FIG. 4B(a) corresponds to a view of the substrate W viewed from below in the +z direction, and FIG. 4B(b) corresponds to a view of the substrate W viewed from the side in the +y direction.

As illustrated in FIG. 4B(a), the substrate W is rotated counterclockwise when viewed from below. The tangential direction of the rotation direction of the substrate W in the liquid landing region (region of x≈0 and y<0) of the cleaning liquid from the spray nozzle 52 is the +direction. On the other hand, the cleaning liquid supply direction from the cleaning liquid supply nozzles 51 and 52 is the −x direction. As described above, the tangential direction of the rotation direction of the substrate W in the liquid landing region does not coincide with the supply direction of the cleaning liquid.

FIG. 4B(b) illustrates an example in which the rotation direction of the scrub cleaning member 21 is a counterclockwise direction when viewed from the side in the +y direction, and the rotation direction of the scrub cleaning member 22 is a clockwise direction (that is, in the region where the cleaning liquid is supplied from the spray nozzle 52, at the position where the scrub cleaning members 21 and 22 contact the substrate W, the tangential direction of the rotation direction of the scrub cleaning members 21 and 22 and the tangential direction of the rotation direction of the substrate W are the same direction). However, the rotation directions may be reverse.

On the lower surface of the substrate W, since the flow of the cleaning liquid layer 92 is in the +x direction and the rotation direction of the scrub cleaning member 22 is also the clockwise direction, most of the scraped defects 95 are caused to flow in the +x direction.

On the other hand, the cleaning liquid supply direction from the spray nozzle 52 is the −x direction, and is opposite to the flow of the cleaning liquid layer 92 (+x direction). The cleaning liquid from the spray nozzle 52 is repelled by the cleaning liquid layer 92 and falls downward because the striking force is weak and the droplets are fine. In this case, since the cleaning liquid drops together with the defects 95, the defects 95 can be efficiently discharged downward.

As described above, even in a case where the supply direction of the cleaning liquid in the liquid landing region does not coincide with the rotation direction of the substrate W, the cleaning liquid supply from the spray nozzle 52 particularly effectively acts on the lower surface of the substrate W, and defects can be efficiently removed.

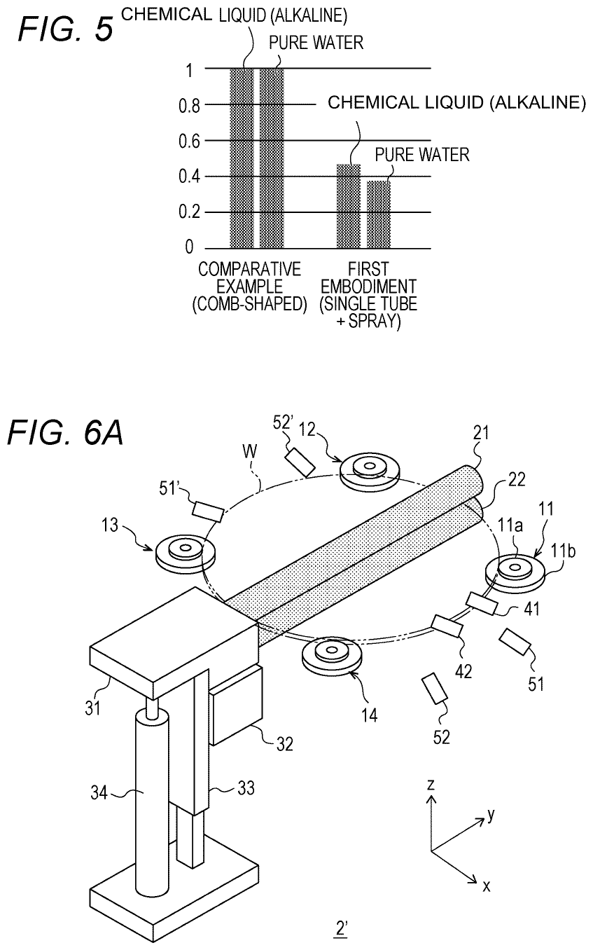

FIG. 5 is a diagram illustrating an experimental result of comparing the cleanability on the lower surface of the substrate W between the substrate cleaning device 2 according to the first embodiment and a substrate cleaning device according to a comparative example.

In the substrate cleaning device according to the comparative example, the cleaning liquid supply nozzles 51 and 52 of the substrate cleaning device 2 according to the first embodiment are all replaced with comb-shaped nozzles. The comb-shaped nozzle is provided with about 10 to 15 holes in a rod-shaped tube extending in parallel with the scrub cleaning member 22, and a cleaning liquid is supplied from each hole to the entire lower surface of the substrate W.

The substrate cleaning device 2 according to the first embodiment and the substrate cleaning device according to the comparative example were made to have the same conditions such as a cleaning liquid supply amount per unit time and a rotation speed and a rotation direction of the substrate W.

The vertical axis in FIG. 5 is obtained by normalizing the number of defects after cleaning is performed for a certain period of time in the comparative example. As illustrated in the drawing, in the substrate cleaning device 2 according to the present embodiment using the single-tube nozzle 51 and the spray nozzle 52 instead of the comb-shaped nozzle, the number of defects remaining on the back surface of the substrate W can be reduced to about 40% in both cases where the cleaning liquid is an alkaline chemical liquid and where the cleaning liquid is pure water.

As described above, in the first embodiment, scrub cleaning is performed while the cleaning liquids are supplied from the single-tube nozzle 51 and the spray nozzle 52 to the lower surface of the substrate W. Consequently, it is possible to efficiently remove defects such as a polishing liquid attached at the time of polishing the substrate from the lower surface of the substrate W.

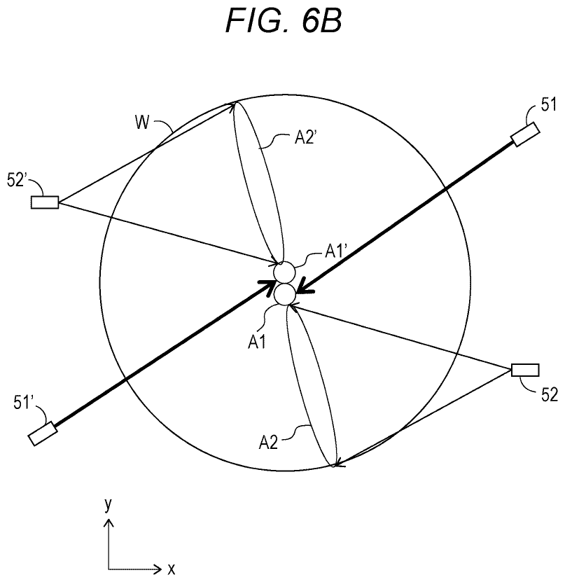

FIG. 6A is a schematic perspective view of a substrate cleaning device 2 which is a modification of the substrate cleaning device 2 in FIG. 2, and an additional single-tube nozzle 51′ and spray nozzle 52′ are provided (however, one of the single-tube nozzle 51′ and the spray nozzle 52′ may be omitted). FIG. 6B is a diagram for describing cleaning liquid supply regions from the cleaning liquid supply nozzles 51, 52, 51′, and 52′ in that case, and corresponds to a view of the substrate W viewed from below in the +z direction (however, the scrub cleaning member 22 is not illustrated).

The single-tube nozzle 51′ is disposed below the substrate W and at a position point-symmetrical to the single-tube nozzle 51 with respect to the center of the substrate W when viewed from vertically above. The single-tube nozzle 51 and the single-tube nozzle 51′ are desirably coplanar.

The spray nozzle 52′ is disposed below the substrate W and at a position point-symmetrical to the spray nozzle 52 with respect to the center of the substrate W when viewed from vertically above. The spray nozzle 52 and the spray nozzle 52′ are desirably coplanar.

As illustrated in FIG. 6B, a cleaning liquid from the single-tube nozzle 51 is supplied to a liquid landing region A1 in the vicinity of the center of the substrate W. A cleaning liquid from the single-tube nozzle 51′ is supplied to a liquid landing region A1′ in the vicinity of the center of the substrate W. The liquid landing region A1 and the liquid landing region A1′ are desirably located at different positions. However, each of the regions desirably includes the vicinity of the center of the substrate W.

A cleaning liquid from the spray nozzle 52 is supplied to a liquid landing region A2 covering the edge from the center of the substrate W. The liquid landing region A2 is a region of x≈0 and y<0. A cleaning liquid from the spray nozzle 52′ is supplied to the liquid landing region A2′ covering the edge from the center of the substrate W. The liquid landing region A2′ is desirably a region of x≈0 and y>0.

### Second Embodiment

The second embodiment is a modification of the substrate cleaning device 2 described in the first embodiment. Hereinafter, a description will focus on differences from the first embodiment.

A substrate cleaning device 2′ according to the second embodiment is obtained by replacing the spray nozzle 52 in the substrate cleaning device 2 according to the first embodiment with a single-tube nozzle 53.

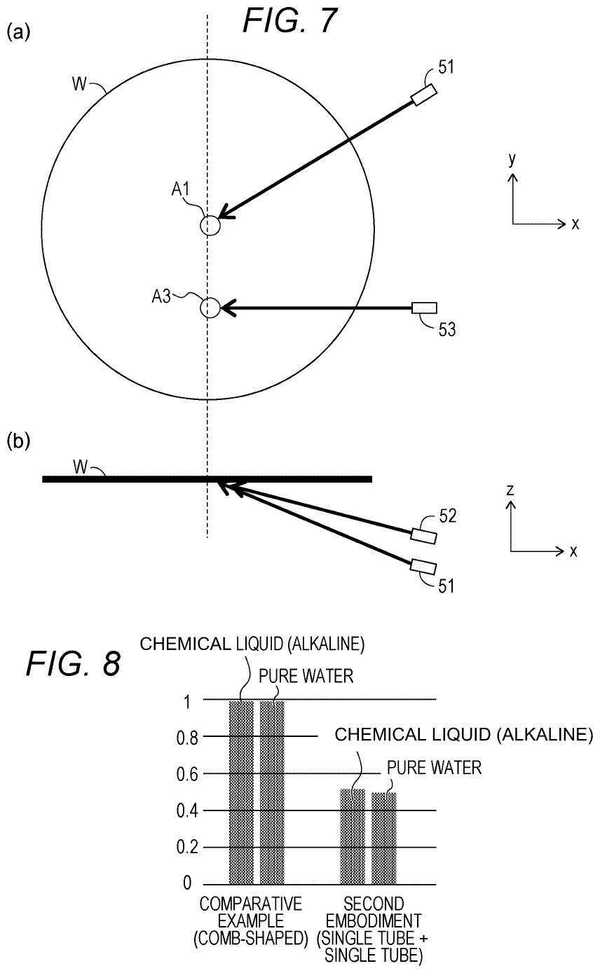

FIG. 7 is a diagram for describing cleaning liquid supply regions from the single-tube nozzles 51 and 53, in which FIG. 7(a) corresponds to a view of the substrate W viewed from below in the +z direction, and FIG. 7(b) corresponds to a view of the substrate W viewed from the side in the +y direction.

As illustrated in the drawing, a cleaning liquid from the single-tube nozzle 51 is supplied to a narrow liquid landing region A1 including (or the vicinity of) the center of the substrate W. A cleaning liquid from the single-tube nozzle 53 is supplied to a narrow liquid landing region A3 in the vicinity of the scrub cleaning member 22 (not illustrated in FIG. 7) and between the center and the edge of the substrate W. It can be said that the liquid landing region A3 of the cleaning liquid from the single-tube nozzle 53 is a region of x=0 and y<0. The cleaning liquid supply direction from the single-tube nozzle 53 may be a direction orthogonal to the scrub cleaning member 22.

FIG. 8 is a diagram illustrating an experimental result of comparing the cleanability on the lower surface of the substrate W between the substrate cleaning device 2′ according to the second embodiment and a substrate cleaning device according to a comparative example. A comparison method is similar to that in FIG. 7, and a comb-shaped nozzle was used in the comparative example. As illustrated in the drawing, in the substrate cleaning device 2′ of the present embodiment using the single-tube nozzles 51 and 53 instead of the comb-shaped nozzles, the number of defects remaining on the back surface of the substrate W can be reduced to about 50% in both cases where the cleaning liquid is a chemical liquid and where the cleaning liquid is pure water.

The reason why defects can be efficiently removed by using the single-tube nozzles 51 and 53 rather than the comb-shaped nozzles is as follows.

Since the comb-shaped nozzle supplies the cleaning liquid from 10 to 15 holes, in a case where a cleaning liquid supply amount per unit time is equal, the single-tube nozzles 51 and 53 have a stronger striking force of the cleaning liquid and a higher striking force (driving force in the horizontal direction) of the cleaning liquid layer. Therefore, the force for discharging the defects in the horizontal direction increases.

Moreover, in the case of the comb-shaped nozzle, since the cleaning liquid is supplied to a wide region, the cleaning liquid can be intensively supplied from the single-tube nozzle 51 to the central portion of the substrate W. Therefore, in the case of using the single-tube nozzle 51, it is possible to suppress a decrease in detergency in the vicinity of the center of the substrate W where the effect of rotation is reduced.

In the present embodiment, compared with the first embodiment using the spray nozzle 52, the action of dropping defects downward is relatively small, but the cleaning effect is higher than that of the comparative example using the comb-shaped nozzle.

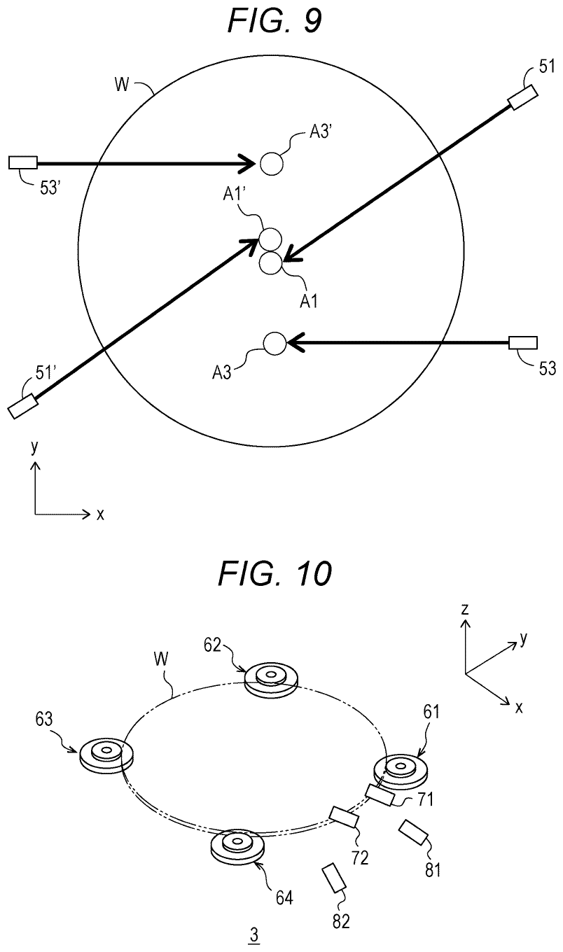

Note that, as in FIG. 6A, additional single-tube nozzles 51′ and 53′ may be provided (however, one of the single-tube nozzles 51′ and 53′ may be omitted). FIG. 9 is a diagram for describing cleaning liquid supply regions from the single-tube nozzles 51, 53, 51′, and 53′ in that case, and corresponds to a view of the substrate W viewed from below in the +z direction (however, the scrub cleaning member 22 is not illustrated).

The single-tube nozzle 51′ is disposed below the substrate W and at a position point-symmetrical to the single-tube nozzle 51 with respect to the center of the substrate W when viewed from vertically above. The single-tube nozzle 51 and the single-tube nozzle 51′ may be coplanar.

The single-tube nozzle 53′ is disposed below the substrate W and at a position point-symmetrical to the single-tube nozzle 53 with respect to the center of the substrate W when viewed from vertically above. The single-tube nozzle 53 and the single-tube nozzle 53′ may be coplanar.

A cleaning liquid from the single-tube nozzle 51 is supplied to the liquid landing region A1 in the vicinity of the center of the substrate W. A cleaning liquid from the single-tube nozzle 51′ is supplied to a liquid landing region A1′ in the vicinity of the center of the substrate W. The liquid landing region A1′ and the liquid landing region A1′ are desirably different regions. However, each of the regions desirably includes the center of the substrate W.

A cleaning liquid from the single-tube nozzle 53 is supplied to a liquid landing region A3 between the center and the edge of the substrate W. The liquid landing region A3 of the cleaning liquid from the single-tube nozzle 53 is a region of x=0 and y<0. A cleaning liquid from the single-tube nozzle 53′ is supplied to a liquid landing region A3′ between the center and the edge of the substrate W. The liquid landing region A3′ of the cleaning liquid from the single-tube nozzle 53′ is a region of x=0 and y>0.

### Third Embodiment

In a third embodiment, the substrate cleaning device 3 in FIG. 1 will be described in detail. The substrate cleaning device 3 replaces the cleaning liquid used for cleaning in the substrate cleaning device 2 and remaining on the surface of the substrate W with pure water.

FIG. 10 is a schematic perspective view of the substrate cleaning device 3 according to the third embodiment. The substrate cleaning device 4 includes substrate rotation mechanisms 61 to 64, pure water supply nozzles 71 and 72 for an upper surface, and pure water supply nozzles 81 and 82 for a lower surface. Compared with the substrate cleaning device 2 illustrated in FIG. 2, the scrub cleaning members 21 and 22 and the rotation mechanisms 31 and 32 related thereto, the guide rail 33, and the lifting/lowering drive mechanism 34 may be omitted. The other configurations are the same as those of the substrate cleaning device 2 illustrated in FIG. 2.

As one feature of the present embodiment, the pure water supply nozzle 81 for a lower surface is a single-tube nozzle (hereinafter, referred to as a “single-tube nozzle 81” in some cases), and the pure water supply nozzle 82 is a spray nozzle (hereinafter, referred to as a “spray nozzle 82” in some cases). The liquid landing regions of the pure water supplied from these nozzles are the same as those illustrated in FIG. 3.

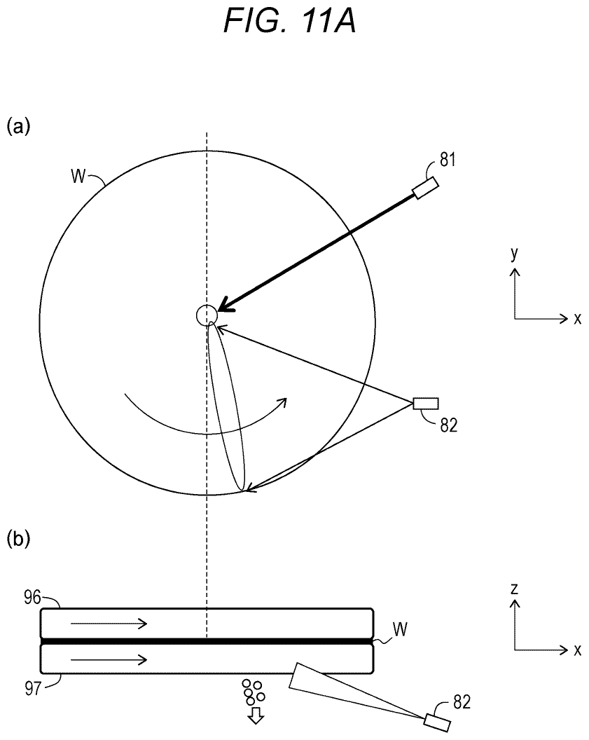

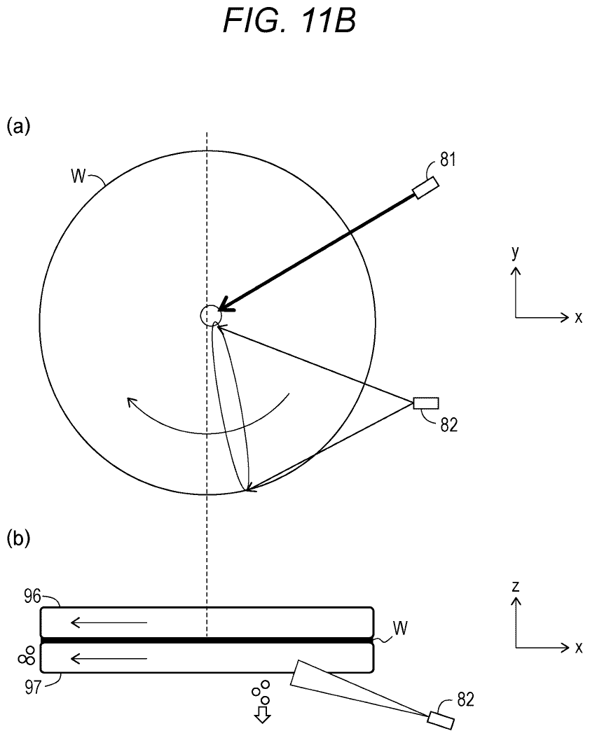

FIG. 11A is a diagram schematically illustrating a state of cleaning in a case where the rotation direction of the substrate W in the liquid landing region does not coincide with the supply direction of the cleaning liquid. FIG. 11A(a) corresponds to a view of the substrate W viewed from below in the +z direction, and FIG. 11B(b) corresponds to a view of the substrate W viewed from the side in the +y direction.

As illustrated in FIG. 11A(a), the substrate W is rotated counterclockwise when viewed from below. The tangential direction of the rotation direction of the substrate W in the liquid landing region (a region of x≈0 and y<0) of the cleaning liquid from the spray nozzle 82 is the +direction. On the other hand, the pure water supply direction from the pure water supply nozzles 81 and 82 is the −x direction. As described above, the tangential direction of the rotation direction of the substrate W in the liquid landing region does not coincide with the pure water supply direction.

Cleaning liquid layers 96 and 97 used in the substrate cleaning device 2 remain on the upper surface and the lower surface of the substrate W, respectively.

On the lower surface of the substrate W, the flow of the cleaning liquid layer 97 is in the +x direction. On the other hand, the pure water supply direction from the spray nozzle 82 is the −x direction and is opposite to the flow of the cleaning liquid layer 97 (+x direction). Small droplets of the pure water from the spray nozzle 82 discontinuously disperse and collide in a wide range, and the momentum (mass) of the droplets is small. Therefore, the flow velocity in the horizontal direction after the droplets collide with the cleaning liquid layer 97 is small, and the droplets are repelled by the cleaning liquid layer 97 and fall downward. In this case, since the pure water falls together with the cleaning liquid layer 97, the cleaning liquid layer 97 can be efficiently discharged downward.

Note that even if the spray nozzle 82 is a single-tube nozzle, a certain effect is obtained, but the spray nozzle 82 is more desirable. When pure water is supplied from the single-tube nozzle, the pure water landed on the substrate W falls due to gravity before sufficiently spreading. Therefore, the cleaning liquid layer 97 cannot be efficiently removed in a region away from the liquid landing region in the substrate W. In contrast, since the spray nozzle 82 can supply pure water to a wide region and can widen the liquid landing region itself, the cleaning liquid layer 97 can be efficiently removed in a wide region without falling due to gravity before the pure water sufficiently spreads.

In addition, when pure water is supplied from the single-tube nozzle, since the striking force of the pure water is strong, the pure water easily flows backward along the substrate W on the lower surface of the substrate W, and stagnation of the liquid occurs, so that replacement of the cleaning liquid layer 97 with pure water is difficult. In contrast, since the spray nozzle 82 supplies pure water with a weak striking force, the pure water does not flow backward along the substrate W and is easily repelled and falls downward. As a result, the cleaning liquid layer 97 can be efficiently removed downward.

The single-tube nozzle 81 as well as the spray nozzle 82 is provided for the following reason. Since the cleaning liquid from the spray nozzle 82 lands in a wide region, an amount of the cleaning liquid supplied to the center of the substrate W is reduced. Since a rotation speed of the center of the substrate W is relatively low, the liquid flow is poor, and if the amount of the cleaning liquid is small, the detergency may not be sufficient. Therefore, in order to supply a sufficient amount of the cleaning liquid to the center of the substrate W, the cleaning liquid is supplied from the single-tube nozzle 81 toward the center of the substrate W.

FIG. 11B is a diagram schematically illustrating a state of cleaning in a case where the rotation direction of the substrate W in the liquid landing region coincides with the supply direction of the cleaning liquid, in which FIG. 11B(a) corresponds to a view of the substrate W viewed from below in the +z direction, and FIG. 11B(b) corresponds to a view of the substrate W viewed from the side in the +y direction.

As illustrated in FIG. 11B(a), the substrate W is rotated clockwise when viewed from below. The tangential direction of the rotation direction of the substrate W in the liquid landing region (region of x≈0 and y<0) of the cleaning liquid from the spray nozzle 82 is the −x direction. The pure water supply direction from the pure water supply nozzles 81 and 82 is also the −x direction. As described above, the tangential direction of the rotation direction of the substrate W in the liquid landing region coincides with the supply direction of the cleaning liquid. In this case, the cleaning liquid layer 97 is removed in the horizontal direction due to the rotation of the substrate W, and the cleaning liquid layer 97 is removed downward by the pure water from the pure water supply nozzles 81 and 82. In particular, in a case where predetermined conditions described below are satisfied, the cleaning liquid layer 97 can be more efficiently replaced with the pure water.

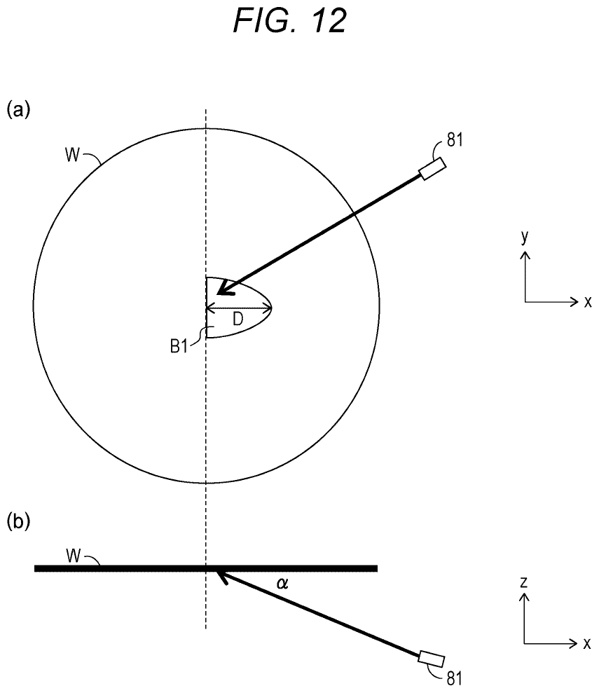

FIG. 12 is a diagram for describing a desirable pure water supply region from the single-tube nozzle 81, in which FIG. 12(a) corresponds to a view of the substrate W viewed from below, and FIG. 12(b) corresponds to a view of the substrate W viewed from the side.

As illustrated in FIG. 12(a), the single-tube nozzle 81 desirably supplies pure water so that a liquid landing region falls within a region B1 of 0<x<D, which is before the center of the substrate W (on the single-tube nozzle 81 side). This is because when the liquid landing region is in the region of x<0, the detergency at the center of the substrate W having a low rotation speed is insufficient. In addition, this is because when the liquid landing region is too close to the edge of the substrate W (a region where x is too large) and the single-tube nozzle 81 needs to be directed upward, the ability to discharge the cleaning liquid layer 97 formed on the lower surface of the substrate W deteriorates.

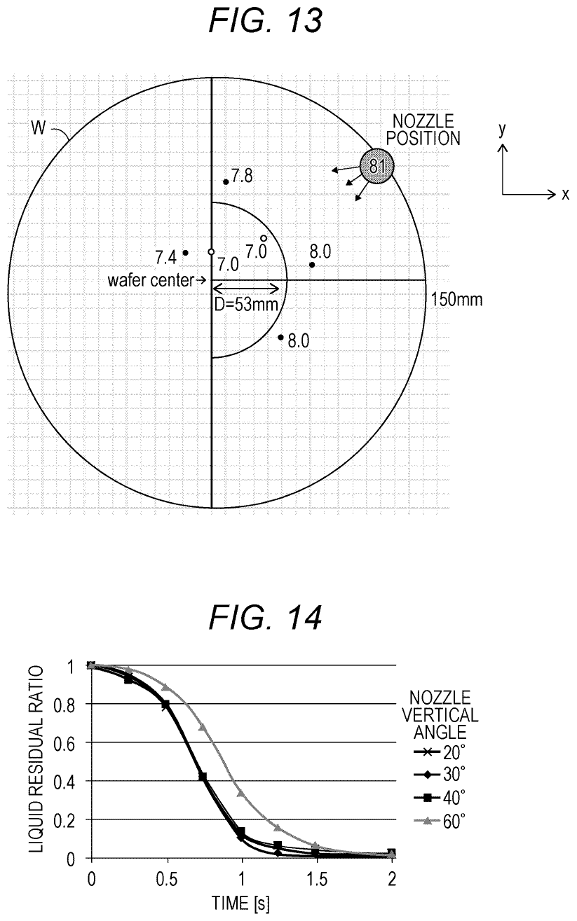

FIG. 13 is a diagram experimentally illustrating a relationship between a liquid landing region of pure water and detergency. The position indicated as “nozzle position” is a disposition position of the single-tube nozzle 81, and six small circles indicate liquid landing regions. pH after pure water is supplied to each liquid landing region under a certain condition on the lower surface of the substrate W on which an alkaline cleaning liquid layer is formed is indicated by a numerical value.

In a case where there is a liquid landing region in the region of x<0, pH after the supply of pure water is 7.4, and the alkaline cleaning liquid is not sufficiently removed. In a case where there is a liquid landing region in the region of 53 mm<x, pH after the supply of pure water is 7.8 or 8.0, and the alkaline cleaning liquid is not sufficiently removed. In contrast, in a case where there is a liquid landing region in the region of 0<x<D=53 mm, pH after the supply of pure water is 7.0, and the alkaline cleaning liquid is sufficiently removed.

From the above description, in a case where the diameter of the substrate W is 300 mm, D is desirably 50 mm or less, and more desirably 30 mm or less. In general, D is desirably 16% or less of the diameter of the substrate W.

Returning to FIG. 12, an angle (hereinafter, referred to as a “vertical angle”) α formed by the substrate W and the pure water supply direction is desirably 10 degrees to 60 degrees, more desirably 20 degrees to 40 degrees, and still more desirably 30 degrees to 35 degrees. This is because in a case where the vertical angle α is too large (close to 90 degrees), the ability to discharge the cleaning liquid layer 97 in the horizontal direction deteriorates. This is because in a case where the vertical angle α is too small (less than 10 degrees), the ability to discharge the cleaning liquid layer 97 downward deteriorates.

FIG. 14 is a diagram experimentally illustrating a relationship between the vertical angle and the detergency. FIG. 14 illustrates a time change in a residual ratio of the cleaning liquid layer remaining on the lower surface of the substrate W in a case where the vertical angle is 20 degrees, 30 degrees, 40 degrees, and 60 degrees. The detergency is particularly noticeable for 1 to 1.25 seconds, and it can be seen that the vertical angle is desirably between 20 degrees and 40 degrees, and more desirably 30 degrees.

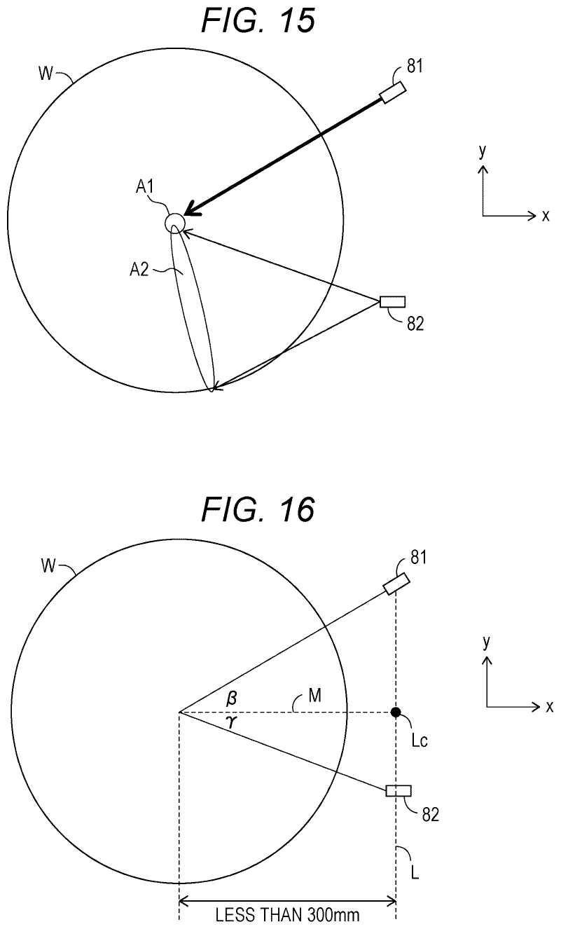

FIG. 15 is a diagram for describing a desirable pure water supply region from the spray nozzle 82, and corresponds to a view of the substrate W viewed from below.

As illustrated in the drawing, it is desirable to supply pure water from the spray nozzle 82 to the spray nozzle 82 side from a line connecting the single-tube nozzle 81 and the center of the substrate W. Specifically, the liquid landing region A3 of the pure water supplied from the spray nozzle 82 at least partially overlaps the liquid landing region A4 of the pure water supplied from the single-tube nozzle 81. The liquid landing region A3 reaches the edge of the substrate W. This is because in a case where the pure water does not reach the edge, the efficiency of replacing the cleaning liquid layer 97 at the edge with the pure water decreases.

Note that an angle (vertical angle) formed by the substrate W and the pure water supply direction from the spray nozzle 82 is desirably 15 degrees to 60 degrees, more desirably 20 degrees to 40 degrees, and still more desirably 30 degrees to 35 degrees, similarly to the single-tube nozzle 81.

FIG. 16 is a diagram for describing desirable disposition of the pure water supply nozzles 81 and 82 when viewed from vertically above. A distance between a line L connecting the single-tube nozzle 81 and the spray nozzle 82 and the center of the substrate W is desirably 300 mm or less. In addition, when a line connecting the center of the substrate W and a center Lc of the line L is defined as a reference line M, an angle β formed by the reference line M and the line connecting the single-tube nozzle 81 and the center of the substrate W is desirably 0 degrees to 75 degrees, and more desirably 15 degrees to 45 degrees. In addition, an angle γ formed by the reference line M and the line connecting the spray nozzle 82 and the center of the substrate W is desirably 0 degrees to −75 degrees, and more desirably −15 degrees to −45 degrees. This is because the pure water from the single-tube nozzle 81 and the pure water from the spray nozzle 82 are mixed, and the cleaning liquid layer 97 near the center of the substrate W is efficiently discharged in the horizontal direction. In particular, the single-tube nozzle 81 preferably has a certain degree of the angle β in order to efficiently discharge the cleaning liquid layer 97 in the horizontal direction.

As described above, in the third embodiment, pure water is supplied from the single-tube nozzle 81 and the spray nozzle 82 to the lower surface of the substrate W to perform cleaning. As a result, the cleaning liquid remaining at the time of substrate cleaning in the substrate cleaning device 2 can be efficiently removed from the lower surface of the substrate W.

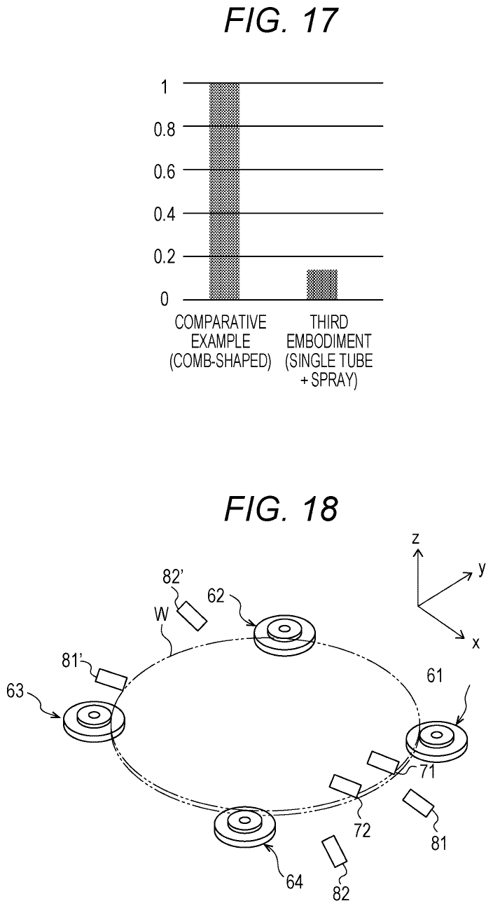

FIG. 17 is a diagram illustrating an experimental result of comparing the cleanability on the lower surface of the substrate W between the substrate cleaning device 3 according to the third embodiment and a substrate cleaning device according to a comparative example. The vertical axis is obtained by normalizing the time required to remove a cleaning liquid layer remaining on the lower surface of the substrate W in the comparative example. A comparison method is similar to that in FIG. 7, and a comb-shaped nozzle was used as a comparative example. As illustrated in the drawing, in the substrate cleaning device 3 of the present embodiment using the single-tube nozzle 81 and the spray nozzle 82 instead of the comb-shaped nozzle, the time required to remove the cleaning liquid could be reduced to 20% or less.

As in FIG. 6A, the substrate cleaning device 3 may have an additional single-tube nozzle 81′ and spray nozzle 82′ (see FIG. 18. However, one of the single-tube nozzle 81′ and the spray nozzle 82′ may be omitted).

### Fourth Embodiment

A fourth embodiment is a modification of the substrate cleaning device 3 described in the third embodiment. Hereinafter, a description will focus on differences from the third embodiment.

The substrate cleaning device 3′ according to the fourth embodiment is obtained by replacing the spray nozzle 82 in the substrate cleaning device 3 according to the third embodiment with a single-tube nozzle. In this case, liquid landing regions of pure water are the same as those illustrated in FIG. 7.

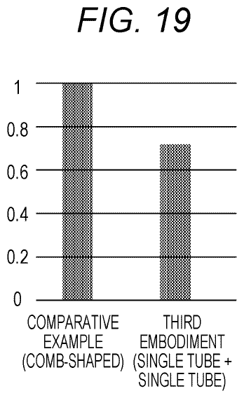

FIG. 19 illustrates results of an experiment on the cleanability in this case. The vertical axis is obtained by normalizing the time required to remove a cleaning liquid layer remaining on the lower surface of the substrate W in the comparative example. A comparison method is similar to that in FIG. 17. As illustrated in the drawing, even when the spray nozzle was replaced with a single-tube nozzle, the time required to remove the cleaning liquid could be reduced to about 70% as compared with the comb-shaped nozzle.

As in FIG. 9, an additional single-tube nozzle may be provided (however, one of the nozzles corresponding to the single-tube nozzles 51′ and 53′ in FIG. 9 may be omitted).

In the embodiment described above, the substrate cleaning device 2 and the substrate cleaning device 3 are separate devices. However, in a case where the cleaning liquid used in the substrate cleaning device 2 is pure water, the substrate cleaning devices 2 and 3 may be integrated. In this case, pure water is supplied to the upper surface and the lower surface of the substrate while scrubbing and cleaning the polished substrate with the scrub cleaning members 21 and 22 to remove defects generated due to polishing. Next, in a state in which the scrub cleaning member 21 has been moved upward and the scrub cleaning member 22 has been moved downward, pure water is supplied to the upper surface and the lower surface of the substrate to remove the pure water remaining on the upper surface and the lower surface of the substrate.

On the basis of the above description, a person skilled in the art may be able to conceive of additional effects and various modifications of the present invention, but aspects of the present invention are not limited to the individual embodiments described above. Various additions, modifications, and partial deletions can be made without departing from the conceptual idea and spirit of the present invention derived from the contents defined in the claims and equivalents thereof.

For example, a device described as a single device (alternatively, a member; the same applies hereinafter) (including a device depicted in the drawings as a single device) in the present specification may be implemented by a plurality of devices. Conversely, devices described as a plurality of devices (including devices depicted in the drawings as a plurality of devices) in the present specification may be implemented by one device. Alternatively, some or all of means or functions assumed to be included in a certain device may be included in another device.

In addition, all the matters described in the present specification are not essential requirements. In particular, matters described in the present specification and not described in the claims can be regarded as any additional matters.

It should be noted that the applicant of the present invention is merely aware of the invention disclosed in the document in the section of “Citation List” in the present specification, and the present invention is not necessarily intended to solve the problem in the invention disclosed in the document. The problem to be solved by the present invention should be recognized in consideration of the entire specification. For example, in the present specification, in a case where there is a description that a predetermined effect is exhibited by a specific configuration, it can be said that the problem of reversing the predetermined effect is solved. However, such a specific configuration is not necessarily an essential requirement.

### REFERENCE SIGNS LIST

100 substrate processing apparatus
1 substrate polishing device
2, 3 substrate cleaning device
11 to 14, 61 to 64 substrate rotation mechanism
21, 22 scrub cleaning member
31, 32 rotation mechanism
33 guide rail
34 lifting/lowering drive mechanism
41, 42, 71, 72 cleaning liquid supply nozzle
51, 51′, 53, 53′, 81, 81′ single-tube nozzle
52, 52′, 82 spray nozzle
91, 92, 96, 97 cleaning liquid layer
93 to 95 defect

1. A substrate cleaning device comprising:
a first scrub cleaning member that scrubs and cleans a lower surface of a substrate that is a cleaning target;
a first single-tube nozzle that supplies cleaning liquid to a vicinity of a center of the lower surface of the substrate; and
a first spray nozzle that supplies cleaning liquid to the lower surface of the substrate.

2. The substrate cleaning device according to claim 1, wherein a liquid landing region of the cleaning liquid supplied from the first spray nozzle covers a region from a vicinity of a center of the substrate to a vicinity of an edge of the substrate.

3. The substrate cleaning device according to claim 1, further comprising at least one of:
a second single-tube nozzle that is disposed at a position point-symmetrical to the first single-tube nozzle with respect to the center of the substrate when viewed from vertically above and supplies cleaning liquid to a region that is in a vicinity of the center of the lower surface of the substrate and is different from cleaning liquid supply region from the first single-tube nozzle; and
a second spray nozzle that is disposed at a position point-symmetrical to the first spray nozzle with respect to the center of the substrate when viewed from vertically above and supplies cleaning liquid to the lower surface of the substrate.

4. A substrate cleaning device comprising:
a first scrub cleaning member that scrubs and cleans a lower surface of a substrate that is a cleaning target;
a first single-tube nozzle that supplies cleaning liquid to a vicinity of a center of the lower surface of the substrate; and
a second single-tube nozzle that supplies cleaning liquid to a region different from the vicinity of the center of the lower surface of the substrate.

5. The substrate cleaning device according to claim 4, further comprising at least one of:
a third single-tube nozzle that is disposed at a position point-symmetrical to the first single-tube nozzle with respect to the center of the substrate when viewed from vertically above and supplies cleaning liquid to a region that is in a vicinity of the center of the lower surface of the substrate and is different from cleaning liquid supply region from the first single-tube nozzle; and
a fourth single-tube that is disposed at a position point-symmetrical to the second single-tube nozzle with respect to the center of the substrate when viewed from vertically above and supplies cleaning liquid to a region that is different from the vicinity of the center of the lower surface of the substrate.

6. The substrate cleaning device according to claim 1, further comprising:
a second scrub cleaning member that scrubs and cleans an upper surface of the substrate;
a fifth single-tube nozzle that supplies cleaning liquid to a vicinity of a center of the upper surface of the substrate; and
a sixth single-tube nozzle that supplies cleaning liquid to a region different from the vicinity of the center of the upper surface of the substrate.

7. A substrate cleaning device comprising:
a first nozzle that is a single-tube nozzle that supplies pure water to a vicinity of a center of a lower surface of a substrate that is a cleaning target; and
a second nozzle that is a spray nozzle that supplies pure water to the lower surface of the substrate.

8. The substrate cleaning device according to claim 7, further comprising at least one of:
a third nozzle that is a single-tube nozzle that is disposed at a position point-symmetrical to the first nozzle with respect to the center of the substrate when viewed from vertically above and supplies pure water to a region that is in a vicinity of the center of the lower surface of the substrate and is different from pure water supply region from the first nozzle; and
a fourth nozzle that is a spray nozzle that is disposed at a position point-symmetrical to the second nozzle with respect to the center of the substrate when viewed from vertically above and supplies pure water to the lower surface of the substrate.

9. A substrate cleaning device comprising:
a first nozzle that is a single-tube nozzle that supplies pure water to a vicinity of a center of a lower surface of a substrate that is a cleaning target; and
a second nozzle that is a single-tube nozzle that supplies pure water to a region different from a vicinity of the center of the lower surface of the substrate.

10. The substrate cleaning device according to claim 9, further comprising at least one of:
a third nozzle that is a single-tube nozzle disposed at a position point-symmetrical to the first nozzle with respect to the center of the substrate when viewed from vertically above and supplies pure water to a region that is in the vicinity of the center of the lower surface of the substrate and is different from pure water supply region from the first nozzle; and
a fourth nozzle that is a single-tube nozzle disposed at a position point-symmetrical to the second nozzle with respect to the center of the substrate when viewed from vertically above and supplies pure water to a region different from the vicinity of the center of the lower surface of the substrate.

11. The substrate cleaning device according to claim 7, further comprising
a substrate rotation mechanism configured to rotate the substrate, wherein
a supply direction of the pure water supplied from the first nozzle and a tangential direction of a rotation direction of the substrate in a liquid landing region of the pure water supplied from the second nozzle are opposite directions.

12. The substrate cleaning device according to claim 7, further comprising
a substrate rotation mechanism configured to rotate the substrate, wherein
a supply direction of the pure water supplied from the first nozzle and a tangential direction of a rotation direction of the substrate in a liquid landing region of the pure water supplied from the second nozzle are identical directions.

13. The substrate cleaning device according to claim 12, wherein an angle formed by the substrate and the supply direction of the pure water supplied from the first nozzle is 10 to 60 degrees.

14. A substrate processing apparatus comprising:
a substrate polishing device that polishes a substrate by using a polishing liquid;
a first substrate cleaning device that scrubs and cleans the substrate polished by the substrate polishing device by using cleaning liquid; and
a second substrate cleaning device that cleans the substrate cleaned by the first substrate cleaning device by using pure water, wherein
the first substrate cleaning device comprises: is
a first scrub cleaning member that scrubs and cleans a lower surface of a substrate that is a cleaning target;
a first single-tube nozzle that supplies cleaning liquid to a vicinity of a center of the lower surface of the substrate; and
a first spray nozzle that supplies cleaning liquid to the lower surface of the substrate,
the second substrate cleaning device comprises:
a first nozzle that is a single-tube nozzle that supplies pure water to a vicinity of a center of a lower surface of a substrate that is a cleaning target; and
a second nozzle that is a spray nozzle that supplies pure water to the lower surface of the substrate.

15. (canceled)

16. (canceled)

17. (canceled)

18. (canceled)

19. (canceled)

20. (canceled)

21. (canceled)
